(19) United States
(12) Patent Application Publication
(10) Pub. No.: US 2015/0380596 A1
(43) Pub. Date: Dec. 31, 2015

(54) CIGS FILM PRODUCTION METHOD, AND CIGS SOLAR CELL PRODUCTION METHOD USING THE CIGS FILM PRODUCTION METHOD

(71) Applicant: NITTO DENKO CORPORATION, Ibaraki-shi, Osaka (JP)

(72) Inventors: Hiroto Nishii, Ibaraki-shi (JP); Taichi Watanabe, Ibaraki-shi (JP); Yusuke Yamamoto, Ibaraki-shi (JP); Seiki Teraji, Ibaraki-shi (JP); Kazunori Kawamura, Ibaraki-shi (JP)

(73) Assignee: NITTO DENKO CORPORATION, Ibaraki-shi, Osaka (JP)

(21) Appl. No.: 14/766,565

(22) PCT Filed: Jan. 24, 2014
(86) PCT No.: PCT/JP2014/051509

§ 371 Date: Aug. 7, 2015

(30) Foreign Application Priority Data
Feb. 12, 2013 (JP) 2013-024572

(51) Int. Cl. H01L 31/18; H01L 31/0392

(52) U.S. Cl. CPC H01L 31/18; H01L 31/03923

(57) ABSTRACT

The CIGS film production method includes: a stacking step of stacking a layer (A) containing indium, gallium and selenium and a layer (B) containing copper and selenium, in this order in a solid phase over a substrate; and a heating step of heating the resulting stack of the layer (A) and the layer (B) to melt the layer (B) into a liquid phase, whereby copper is diffused from the layer (B) into the layer (A) to cause crystal growth; wherein the layer (A) is formed by repeatedly stacking a gallium selenide film (Y) and an indium selenide film (X) in this order and reducing a thickness ratio (Y/X) between the gallium selenide film (Y) and the indium selenide film (X) as the stacking is repeated.

### TECHNICAL FIELD

The present invention relates to a CIGS film production method which ensures that a CIGS film can be produced with proper reproducibility as having an excellent sunlight conversion efficiency and a Ga/(In+Ga) ratio graded along the thickness thereof, and to a CIGS solar cell production method employing the CIGS film production method.

### BACKGROUND ART

Thin film solar cells typified by amorphous silicon solar cells and compound thin film solar cells allow for significant reduction in material costs and production costs as compared with conventional crystalline silicon solar cells. In recent years, therefore, research and development have been rapidly conducted on these thin film solar cells. Among these thin film solar cells, a CIGS solar cell which is a type of compound thin film solar cell produced by employing Group I, III and VI elements as constituents and including a light absorbing layer composed of an alloy of copper (Cu), indium (In), gallium (Ga) and selenium (Se) is particularly attractive, because the CIGS solar cell is excellent in sunlight conversion efficiency (hereinafter referred to simply as “conversion efficiency”) and is produced without the use of silicon.

The light absorbing layer of the CIGS solar cell is produced by a selenization method, a non-vacuum process (nano particle) method, a vacuum evaporation method or the like. In the vacuum evaporation method, the film is formed through vapor deposition by separately heating Cu, In, Ga and Se evaporation sources. Since the formation of the film is achieved by controlling the feed amounts of the respective elements, the composition of the film can be advantageously controlled along the thickness of the film.

A so-called three-step method, which is a type of multi-source evaporation method out of the vacuum evaporation methods, provides the highest conversion efficiency. As shown in FIG. 16, this method includes three steps. In the first step, In, Ga and Se are vapor-deposited on a substrate, whereby an (In, Ga)₂Se₃ film is formed. Then, the temperature of the substrate is increased to 550° C., and Cu and Se are vapor-deposited, whereby a Cu-rich CIGS film is formed (second step). At this stage, two phases, i.e., liquid phase Cu₍₂₋ₓ₎Se and solid phase CIGS, coexist in the CIGS film, whereby crystal grain size is rapidly increased in the presence of Cu₍₂₋ₓ₎Se.

It is known that Cu₍₂₋ₓ₎Se has a lower resistance and, therefore, adversely influences solar cell characteristics. In the third step of the three-step method, therefore, In, Ga and Se are further vapor-deposited to reduce the proportion of Cu₍₂₋ₓ₎Se after the second step. Thus, the CIGS film has a composition slightly rich in Group III as a whole. The CIGS thin film thus formed by the three-step method has greater crystal grain diameters and yet has a thin film crystal structure having a crystallographically higher quality than a CIGS thin film produced by the conventional evaporation method (see, for example, PTL 1).

Where the CIGS film formed by the three-step method is used for a solar cell, the solar cell indeed has a higher conversion efficiency from a viewpoint of a smaller-area device. However, the CIGS film is produced by supplying liquid phase Cu₍₂₋ₓ₎Se (principal component for crystal growth) from the initial stage, so that Cu is not necessarily uniformly diffused into the film. In a strict sense, therefore, the crystal grains are not necessarily uniform. Further, Cu₍₂₋ₓ₎Se is easily excessively incorporated into the film. Problematically, this impairs the device characteristic properties.

Depending on the heating conditions, the three-step method causes variations in Ga-distribution and In-distribution in the film, making it difficult to control a band gap profile.

### RELATED ART DOCUMENT

### Patent Document

PTL 1: JP-A-HEI10(1998)-513606

### SUMMARY OF INVENTION

In view of the foregoing, it is an object of the present invention to provide a CIGS film production method which ensures that a CIGS film even for use in production of a large-area device can be produced as having an excellent conversion efficiency at lower costs and, in addition, improves the conversion efficiency of the CIGS film by imparting the CIGS film with a Ga/(In+Ga) ratio graded along the thickness of the film and making it possible to control the band gap profile, and to provide a CIGS solar cell production method employing the CIGS film production method.

According to a first aspect of the present invention to achieve the aforementioned object, there is provided a CIGS film production method including: a stacking step of stacking a layer (A) containing indium, gallium and selenium and a layer (B) containing copper and selenium in this order in a solid phase over a substrate; and a heating step of heating the resulting stack of the layer (A) and the layer (B) to melt the layer (B) into a liquid phase, whereby copper is diffused from the layer (B) into the layer (A) to cause crystal growth; wherein the layer (A) is formed by repeatedly stacking a gallium selenide film (Y) and an indium selenide film (X) in this order and reducing a thickness ratio (Y/X) between the gallium selenide film (Y) and the indium selenide film (X) as the stacking is repeated.

According to a second aspect of the present invention, there is provided a CIGS solar cell production method including the steps of: providing a rear electrode layer over a substrate; providing a light absorbing layer of a CIGS film; providing a buffer layer; and providing a transparent electrically-conductive layer; wherein the light absorbing layer of the CIGS film is formed by the CIGS film production method according to the first aspect in the light absorbing layer providing step.

The inventors of the present invention conducted studies on a compound semiconductor solar cell, particularly on a CIGS solar cell, in order to provide a solar cell having a higher light absorbing coefficient and effective for resource saving. As a result, the inventors found that, where the CIGS film serving as the light absorbing layer of the CIGS solar cell is produced, rather than by the conventional three-step method shown in FIG. 16, by first stacking the layer (A) containing In, Ga and Se and the layer (B) containing Cu and Se in this order in the solid phase over the substrate, then heating the resulting stack of the two layers (A) and (B) to melt a compound of Cu and Se in the layer (B) into the liquid phase to diffuse Cu from the layer (B) into the layer (A) to cause crystal growth to provide the CIGS film, crystal grains are uniformly grown to greater sizes in the film and an excess amount of Cu₍₂₋ₓ₎Se is prevented from being incorporated into the film. Further, the inventors found that, where the layer (A) is formed by repeatedly stacking the gallium selenide film (Y) and the indium selenide film (X) in this order and reducing the thickness ratio (Y/X) between the gallium selenide film (Y) and the indium selenide film (X) as the stacking is repeated, the CIGS film can be easily produced with proper reproducibility as having a decreasing gradient in Ga/(In+Ga) ratio along the thickness thereof as shown in FIG. 11, and attained the present invention. Where the GIGS solar cell is produced by employing the inventive GIGS film production method as part of the GIGS solar cell production method, the GIGS solar cell can be produced with proper reproducibility as having a higher conversion efficiency substantially without device-to-device variations in conversion efficiency, because crystal grains are uniformly grown to greater sizes in the GIGS film serving as the light absorbing layer and the GIGS film has a Ga/(In+Ga) ratio graded along the thickness thereof.

In the present invention, the term “solid phase” means a phase in which a substance is in a solid state at a specific temperature, and the term “liquid phase” means a phase in which a substance is in a liquid state at a specific temperature.

In the present invention, the expression “the layer (A) and the layer (B) are stacked over the substrate” means not only that these layers are stacked directly on the substrate, but also that these layers are stacked over the substrate with the intervention of other layer.

In the present invention, the proportion (a) of Ga based on the total amount of In and Ga along the thickness of the GIGS film is measured by means of a D-SIMS (DYNAMIC SIMS) evaluation apparatus (available from Ulvac-Phi, Inc.) The proportion of Cu based on the total amount of In and Ga in the CIGS film is calculated based on atomic number concentrations of Cu, In and Ga of the CIGS film determined by means of an energy dispersive fluorescent X-ray analyzer (EX-250 available from Horiba Corporation) or the D-SIMS described above.

In the present invention, the expression “the film has a decreasing (or increasing) gradient in Ga/(In+Ga) ratio along the thickness thereof” means that the film has a Ga/(In+Ga) ratio graded decreasingly (or increasingly) toward the buffer layer from the rear electrode layer.

In the inventive CIGS film production method, the layer (A) containing In, Ga and Se and the layer (B) containing Cu and Se are first stacked in this order over the substrate. Therefore, the solid phase layer (B) can be stacked on the solid phase layer (A) as having a uniform thickness. At this stage, mutual diffusion between these layers is suppressed. Then, the stack of these two layers (A) and (B) is heated to melt the compound of Cu and Se into the liquid phase in the layer (B), whereby Cu is rapidly diffused from the layer (B) into the layer (A). At this time, Cu is uniformly diffused from the layer (B) into the layer (A), because the layer (B) is formed as having a uniform thickness on the layer (A) in the previous step. Thus, the crystal grains are uniformly grown to greater sizes. Since the layer (B) is once provided in the solid phase, Cu₍₂₋ₓ₎Se is substantially prevented from being excessively incorporated into the CIGS film.

The formation of the layer (A) is achieved by repeatedly stacking the gallium selenide film (Y) and the indium selenide film (X) in this order and reducing the thickness ratio (Y/X) between the gallium selenide film (Y) and the indium selenide film (X) as the stacking is repeated. Therefore, as shown in FIG. 11, the CIGS film can be easily produced with higher reproducibility as having a decreasing gradient in Ga/(In+Ga) ratio along the thickness thereof. Thus, the composition ratio of gallium and indium can be controlled as desired. This means that the band gap can be controlled as desired.

The CIGS film production method may further include a post-stacking step of stacking a layer (C) containing indium, gallium and selenium while maintaining the substrate at the same temperature as in the heating step after the heating step, wherein the layer (C) is formed by repeatedly stacking a gallium selenide film (Y) and an indium selenide film (X) in this order and increasing a thickness ratio (Y/X) between the gallium selenide film (Y) and the indium selenide film (X) as the stacking is repeated. In this case, the layer (C) has an increasing gradient in Ga/(In+Ga) ratio along the thickness of the film. Therefore, the layer (A) and the layer (C) thus formed cooperatively define a V-shaped profile (double-graded structure) including both the decreasing gradient and the increasing gradient as shown in FIG. 12. This makes it possible to improve both the short circuit current and the open circuit voltage.

In the formation of the layer (A), a thickness ratio (Y/X) (i) between a gallium selenide film (Y) and an indium selenide film (X) stacked in the first stacking operation out of repeated stacking operations is 0.5 to 1.3, anda thickness ratio (Y/X) (ii) betweenagallium selenide film (Y) and an indium selenide film (X) stacked in the last stacking operation is 0.2 to 0.5. The thickness ratios (i) and (ii) satisfy a relationship of (i)>(ii). In this case, the Ga/(In+Ga) ratio can be controlled so as to have a predetermined gradient along the thickness of the film, whereby the CIGS solar cell can be produced as having a higher conversion efficiency.

In the formation of the layer (C), a thickness ratio (Y/X)(iii) between a gallium selenide film (Y) and an indium selenide film (X) stacked in the first stacking operation out of repeated stacking operations is 0.2 to 0.5, and a thickness ratio (Y/X) (iv) between a gallium selenide film (Y) and an indium selenide film (X) stacked in the last stacking operation is 0.5 to 1.3. The thickness ratios (iii) and (iv) satisfy a relationship of (iv)>(iii). In this case, the Ga/(In+Ga) ratio can be controlled so as to have a predetermined gradient along the thickness of the film, whereby the CIGS solar cell can be produced as having a higher conversion efficiency.

Where the thickness ratios (Y/X) between the gallium selenide film (Y) and the indium selenide film (X) are each controlled by controlling the evaporation amount of gallium through variable temperature control of a gallium evaporation source, accurate control of the thickness ratios can be achieved at lower costs without the need for a special apparatus.

The CIGS film may satisfy a molar ratio of 0.95<copper/(indium+gallium)<1.30 at the end of the heating step, and may satisfy a molar ratio of 0.70<copper/(indium+gallium)<0.95 at the end of the post-stacking step. In this case, with the CIGS film having a composition satisfying a molar ratio of 0.95<copper/(indium+gallium)<1.30 at the end of the heating step, the Cu component is also sufficiently diffused in an interface between the layer (A) and the layer (B) to cause the crystal growth. In addition, Cu₍₂₋ₓ₎Se is prevented from being excessively incorporated into the CIGS film. Therefore, a device employing the CIGS film is free from reduction in device characteristics. Where the layer (C) of In, Ga and Se is further stacked on the CIGS film after the heating step with the substrate maintained at the same temperature as in the heating step to allow the CIGS film to have a composition satisfying a molar ratio of 0.7<Cu/(In+Ga)<0.95, the CIGS film is slightly Cu-deficient as a whole. Therefore, where the CIGS film is used as a light absorbing layer for a device, the light absorbing layer has a higher efficiency.

Where the stacking step is performed at a temperature of 100° C. to 250° C., mutual diffusion in the interface between the layer (A) and the layer (B) can be minimized. Therefore, the crystal grains can be uniformly grown to greater sizes by heating the stack in the subsequent step. Further, where the heating step is performed at a temperature of not lower than 520° C. after the stacking step, most of the compound of Cu and Se in the layer (B) is melted. Therefore, Cu is rapidly and uniformly diffused from the layer (B) into the layer (A). Thus, the crystal grains are uniformly grown to greater sizes.

Where the temperature is increased at a temperature increasing rate of not less than 10° C./second from the temperature of the stacking step to the temperature of the heating step, the layer (B) is rapidly liquefied and, therefore, Cu is more rapidly diffused from the layer (B) into the layer (A). Thus, the crystal grains are uniformly grown to greater sizes in the film.

Where selenium vapor or hydrogen selenide is supplied in the heating step and a selenium partial pressure is maintained at a higher level in a front surface of the stack than in an inner portion of the stack, Se is substantially prevented from being released from the CIGS film in the heating step. Thus, the composition of the CIGS film can be more advantageously controlled.

Where the CIGS solar cell production method includes the steps of providing the rear electrode layer, providing the light absorbing layer of the CIGS film, providing the buffer layer and providing the transparent electrically-conductive layer, and the light absorbing layer of the CIGS film is formed by the aforementioned CIGS film production method in the light absorbing layer providing step, the CIGS solar cell can be produced as having an excellent conversion efficiency without device-to-device variations in conversion efficiency.

### BRIEF DESCRIPTION OF DRAWINGS

FIG. 1 is a diagram for explaining a CIGS film to be produced according to one embodiment of the present invention.

FIG. 2 is a schematic diagram of an evaporation apparatus to be used for the production of the CIGS

FIG. 3 is a diagram for explaining a producti on method for the CIGS

FIG. 4 is a diagram for explaining the CIGS film production method.

FIG. 5 is a diagram for explaining the CIGS film production method.

FIG. 6 is a diagram for explaining the CIGS film production method.

FIG. 7 is a diagram for explaining the CIGS film production method.

FIG. 8 is a diagram for explaining the CIGS film production method.

FIG. 9 is a diagram for explaining the CIGS film production method.

FIG. 10 is a diagram for explaining a CIGS solar cell to be produced according to another embodiment of the present invention.

FIG. 11 is a graph schematically showing a variation in Ga/(In+Ga) ratio along the thickness of the inventive CIGS film.

FIG. 12 is a graph schematically showing a variation in Ga/(In+Ga) ratio along the thickness of the inventive CIGS film.

FIG. 13 is a graph showing a variation in Ga/(In+Ga) ratio along the thickness of a CIGS film of an inventive example.

FIG. 14 is a graph showing a variation in Ga/(In+Ga) ratio along the thickness of a CIGS film of a conventional example.

FIG. 15 is a schematic diagram for explaining the present invention.

FIG. 16 is a schematic diagram for explaining the conventional example.

### DESCRIPTION OF EMBODIMENTS

Next, embodiments of the present invention will be described.

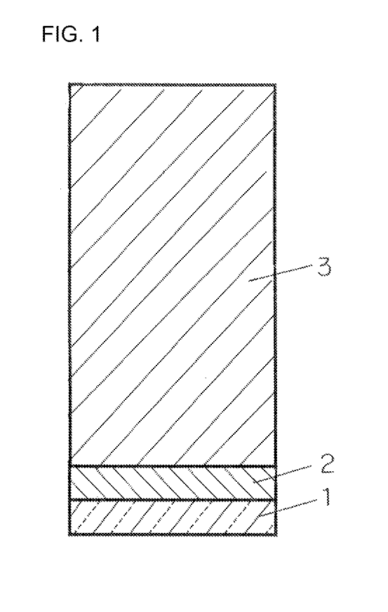

FIG. 1 is a diagram for explaining a CIGS film 3 to be produced according to one embodiment of the present invention. In FIG. 1, the CIGS film 3 is used as a light absorbing layer for a CIGS solar cell. A rear electrode layer 2 of molybdenum (Mo) is provided over a substrate 1 of soda lime glass (SLG), and the CIGS film 3 is provided over the rear electrode layer 2. These components will hereinafter be described in detail, and a method for producing the CIGS film 3 will also be described in detail. In FIG. 1, these components are schematically illustrated, and each have a thickness and a size that are different from the actual thickness and the actual size thereof. (The same is applied to the following figures.)

In FIG. 1, the substrate 1 serves as a support substrate and, other than SLG, a flexible metal foil or the like may be used as the substrate. A material capable of enduring a temperature of not lower than 520° C. is preferably used for the substrate 1 to withstand heating in the subsequent heating step. Examples of the material include stainless steel and titanium. Particularly, ferritic SUS430 is preferred.

The rear electrode layer 2 is formed by a sputtering method. Exemplary materials other than Mo for the rear electrode layer 2 include tungsten, chromium and titanium. The rear electrode layer 2 may have a single layer structure or a multilayer structure. The rear electrode layer 2 preferably has a thickness of 100 nm to 1000 nm.

The CIGS film 3 is made of a compound semiconductor containing four elements, i.e., Cu, In, Ga and Se, and has a thickness of 2.0 μm. The film has a molar ratio of Cu/(In+Ga)≈0.77 with an average composition ratio of Cu:In:Ga=22.1:21.2:7.5.

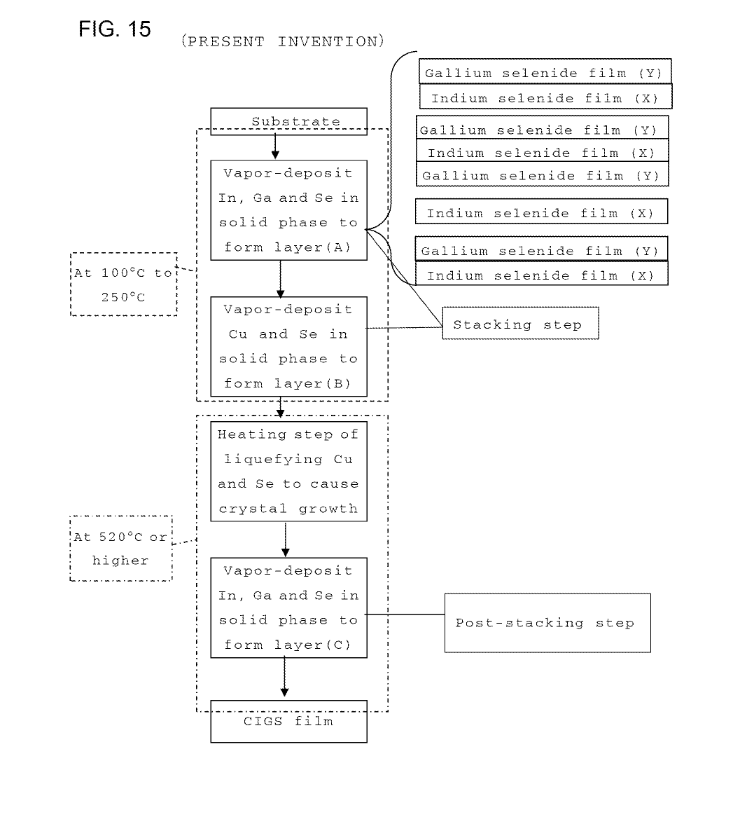

In the embodiment of the present invention, the CIGS film 3 may be produced in the following manner. The production method is schematically shown in FIG. 15. First, a substrate 1 formed with a rear electrode layer 2 is prepared. With the substrate 1 maintained at a retention temperature of 100° C. to 250° C., In, Ga and Se are evaporated on a side of the substrate 1 formed with the rear electrode layer 2 to be thereby vapor-deposited on the rear electrode layer 2 to form a layer (A) over the rear electrode layer 2. In the formation of the layer (A), a gallium selenide film (Y) and an indium selenide film (X) are repeatedly stacked in this order, and the thickness ratio (Y/X) between the gallium selenide film (Y) and the indium selenide film (X) is reduced as the stacking is repeated. Then, Cu and Se are vapor-deposited on the layer (A) thus formed to form a layer (B) on the layer (A). Thus, a stack is provided (stacking step). In turn, the stack is heated to 520° C. or higher to liquefy Cu and Se to cause crystal growth (heating step). Further, In, Ga and Se are vapor-deposited with the substrate maintained at the same temperature as in the heating step (post-stacking step). Thus, the CIGS film 3 is produced.

(Stacking Step)

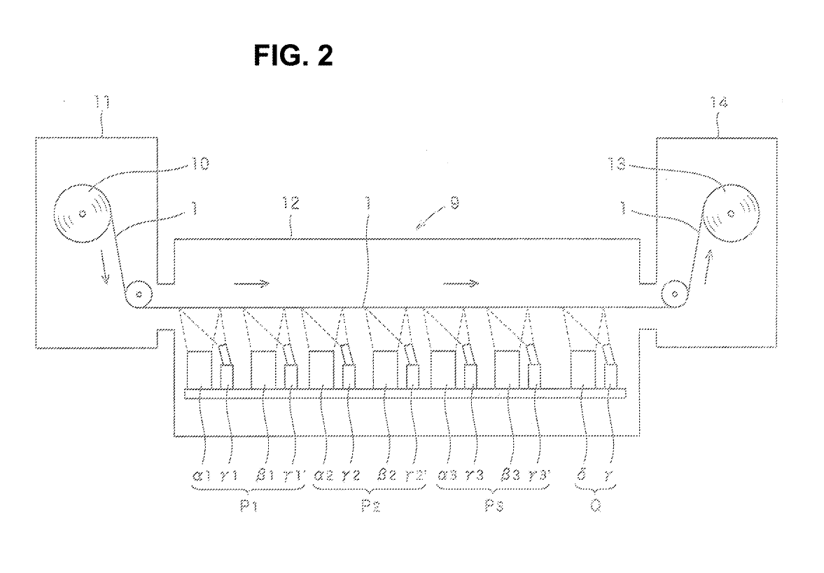

The formation of the layer (A) and the layer (B) will be described in greater detail. For example, an evaporation apparatus 9 as shown in FIG. 2 is used for the formation of the layer (A). The apparatus 9 is capable of forming a vapor deposition layer on a rear electrode layer 2 while conveying an elongated substrate 1 maintained at a substrate temperature of 200° C. by a roll-to-roll method. The apparatus 9 includes a vapor deposition chamber 12 for vapor deposition on the substrate 1, and a wind-up chamber 14 in which a wind-up roll 13 for winding up the substrate 1 subjected to the vapor deposition is accommodated. The vapor deposition chamber 12 includes three stacking blocks (P1, P2, P3) for forming the layer (A), and a stacking block Q for stacking the layer (B). Bypassing the substrate 1 through the chambers 11, 12, 14, therefore, the stacking of the gallium selenide film (Y) and the indium selenide film (x) is repeated three times to form the layer (A) over the elongated substrate 1, and then the layer (B) is formed.

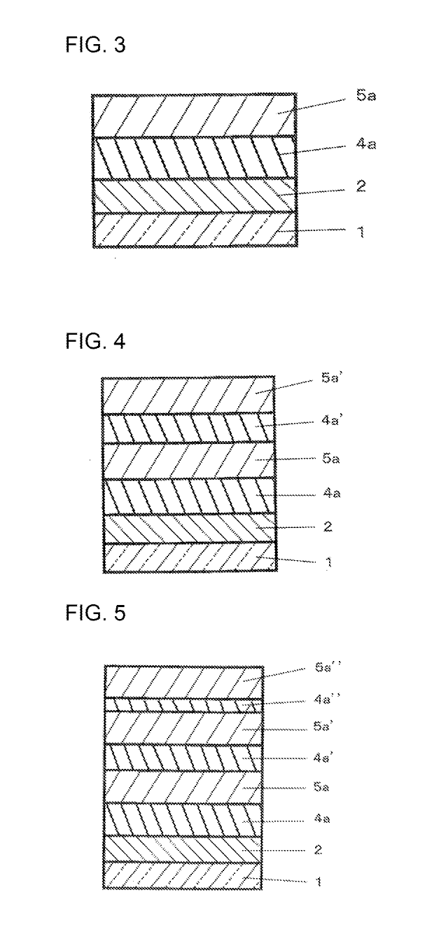

For the formation of the layer (A), the stacking block P1 forms a gallium selenide film (Y) 4a from Ga supplied from an evaporation source α1 and Se supplied from an evaporation source γ1, as shown in FIG. 3, and then forms an indium selenide film (X) 5a from In supplied from an evaporation source β1 and Se supplied from an evaporation source γ1′. Similarly, the stacking blocks P2, P3 also form gallium selenide films (Y) and indium selenide films (X).

As the stacking is repeated, the thickness ratio (Y/x) between the gallium selenide film (Y) and the indium selenide film (x) is reduced, for example, by reducing the temperature of the Ga evaporation source with the temperature of the In evaporation source kept constant as the stacking is repeated. The evaporation apparatus 9 will be described more specifically. The temperature of an evaporation source α2 for the second stacking (in the stacking block P2) is lower than the temperature of the evaporation source α1 for the first stacking (in the stacking block P1), so that the Ga evaporation amount from the evaporation source α2 is controlled to be smaller than the Ga evaporation amount from the evaporation source α1. Thus, as shown in FIG. 4, the gallium selenide film 4a′ formed by the second stacking (in the stacking block P2) has a smaller thickness than the gallium selenide film 4a formed by the first stacking (in the stacking block P1), while the indium selenide films 5a, 5a′ have the same thickness. Similarly, the temperature of an evaporation source α3 for the third stacking (in the stacking block P3) is lower than the temperature of the evaporation source α2 for the second stacking (in the stacking block P2), so that the Ga evaporation amount from the evaporation source α3 is controlled to be smaller than the Ga evaporation amount from the evaporation source α2. Thus, the gallium selenide film 4a″ has a smaller thickness than the gallium selenide film 4a′. The Ga evaporation amount is thus controlled with the In evaporation amount kept constant, whereby the thickness ratio (Y/x) between the gallium selenide film (Y) and the indium selenide film (X) is reduced as the stacking is repeated. At this time, the In evaporation amount may be monitored by means of a quartz oscillation sensor or the like to accurately detect the thickness ratio.

In the formation of the layer (A), a thickness ratio (Y/x) (i) between a gallium selenide film (Y) and an indium selenide film (X) stacked in the first stacking operation (in P1 in this embodiment) out of repeated stacking operations is preferably 0.5 to 1.3, and a thickness ratio (ii) in the last stacking operation (in P3 in this embodiment) is preferably 0.2 to 0.5. Further, the thickness ratios (i) and (ii) are preferably controlled to satisfy a relationship of (i)>(ii). By thus controlling the thickness ratios, the Ga/(In+Ga) ratio can be easily controlled so as to have a predetermined gradient along the thickness of the film.

In the formation of the layer (A), the thickness ratio (Y/X) between the gallium selenide film (Y) and the indium selenide film (X) is controlled by controlling the Ga evaporation amounts through variable temperature control of the Ga evaporation sources. Alternatively, the evaporation amounts may be controlled by variably controlling the opening diameters of the respective evaporation sources.

In the formation of the layer (A), as shown in FIG. 2, the stacking of the gallium selenide film (Y) and the indium selenide film (X) is repeated three times not by way of limitation, but the stacking may be repeated any desired number of times. Particularly, the stacking is preferably repeated 2 to 20 times, so that the Ga/(In+Ga) ratio can be easily controlled so as to have a predetermined gradient along the thickness of the film.

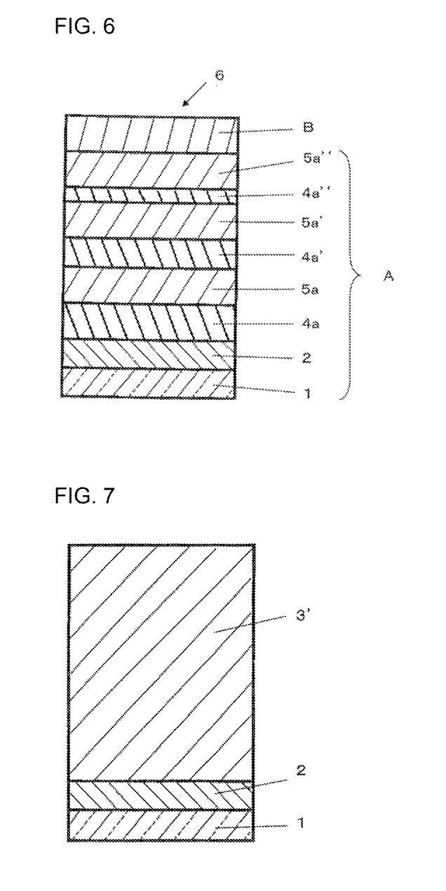

Next, the formation of the layer (B) will be described. After the formation of the layer (A), the layer (B) is formed from Cu supplied from an evaporation source δ and Se supplied from an evaporation source γ in the stacking block Q with the substrate 1 maintained at a temperature of 200° C. to be thereby stacked on the layer (A). Thus, a stack 6 including the layer (A) and the layer (B) stacked on the layer (A) is formed as shown in FIG. 6. At this time, the layer (A) and the layer (B) are each in a solid phase, so that the diffusion between the layers (A) and (B) is minimized. Therefore, the crystal growth does not occur at this stage.

(Heating Step)

In order to melt a compound of Cu and Se into a liquid phase in the layer (B), the stack 6 is heated for 15 minutes with the substrate 1 maintained at a retention temperature of 550° C., while Se vapor is supplied by thermal sublimation. Thus, Cu is diffused from the layer (B) into the layer (A), in which the crystal growth occurs. At this time, the crystal growth occurs parallel to the substrate. In this heating step, the layer (A) and the layer (B) are unified into a CIGS film 3′ (FIG. 7). At this time, the CIGS film 3′ has a molar ratio of Cu/(In+Ga)≈1.00 with a composition ratio of Cu:In:Ga=25.1:18.5:6.4. At this time, the In—Ga composition of the CIGS film 3′ has a concentration distribution such that the In concentration is higher in the front surface of the film 3′ (the Ga concentration is higher on a side of the film 3′ adjacent to the substrate 1).

In the heating step, the temperature is increased at a rate of 10° C./second for setting the temperature. If the temperature increasing rate is excessively low, the liquefaction of the layer (B) proceeds at a lower speed, making it impossible to rapidly diffuse Cu from the layer (B) into the layer (A). This tends to prevent crystal grains from growing to greater sizes. Therefore, the temperature increasing rate is preferably not less than 10° C./second.

(Post-Stacking Step)

Then, the CIGS film 3 is produced by further vapor-depositing In, Ga and Se on the CIGS film 3′ including the layer (A) and the layer (B) unified together while maintaining the substrate 1 at a retention temperature of 550° C. (which is the same temperature as in the heating step) and supplying the thermally sublimated Se vapor to the CIGS film 3′. Thus, the CIGS film 3 is slightly Cu-deficient as a whole.

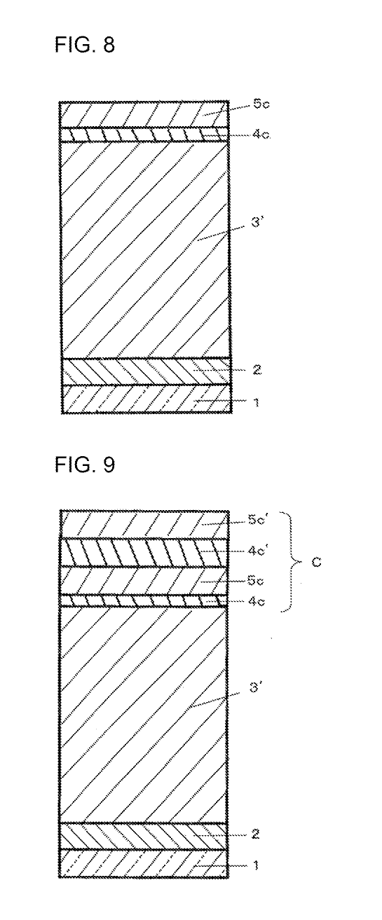

At this time, the formation of the layer (C) is preferably achieved, as shown in FIGS. 8 and 9, by repeatedly stacking the gallium selenide film (Y) and the indium selenide film (X) in this order and increasing the thickness ratio (Y/X) between the gallium selenide film (Y) and the indium selenide film (X) as the stacking is repeated.

That is, the layer (C) may be formed in substantially the same manner as the layer (A). As in the formation of the layer (A), the evaporation apparatus 9 shown in FIG. 2, for example, is used. While the elongated substrate 1 is conveyed by the roll-to-roll method, a gallium selenide film (Y) 4c is first formed on the CIGS film 3′ and then an indium selenide film (X) 5c is formed on the gallium selenide film (Y) 4c as shown in FIG. 8. The stacking of the films (Y) and (X) is repeated, and the thickness ratio (Y/X) between the gallium selenide film (Y) and the indium selenide film (X) is increased as the stacking is repeated.

In the formation of the layer (C), the stacking of the gallium selenide film (Y) and the indium selenide film (X) is repeated twice not by way of limitation, but may be repeated any desired number of times. Particularly, the stacking is preferably repeated 2 to 15 times, so that the Ga/(In+Ga) ratio can be easily controlled so as to have a predetermined gradient along the thickness of the film.

In the layer (C), a thickness ratio (Y/X) (iii) between a gallium selenide film (Y) and an indium selenide film (X) stacked in the first stacking operation out of repeated stacking operations is preferably 0.2 to 0.5, and a thickness ratio (iv) in the last stacking operation is preferably 0.5 to 1.3. Further, the thickness ratios (iii) and (iv) are preferably controlled to satisfy a relationship of (iv)>(iii). By thus controlling the thickness ratios, the Ga/(In+Ga) ratio can be easily controlled so as to have a predetermined gradient along the thickness of the film.

In the CIGS film production method, as described above, the layer (A) containing In, Ga and Se is formed over the substrate 1 at a temperature of 200° C. by repeatedly stacking the gallium selenide film (Y) and the indium selenide film (X) in this order and reducing the thickness ratio (Y/X) between the gallium selenide film (Y) and the indium selenide film (X) as the stacking is repeated. Therefore, the CIGS film can be easily produced as having a Ga/(In+Ga) ratio decreasingly graded along the thickness of the film, as shown in FIG. 11, with higher reproducibility. Then, the layer (B) containing Cu and Se is stacked on the layer (A), and the stack 6 of the layer (A) and the layer (B) is heated for 15 minutes with the substrate 1 maintained at a retention temperature of 550° C. Thus, the compound of Cu and Se in the layer (B) is melted into the liquid phase, whereby Cu is rapidly diffused from the layer (B) into the layer (A). Therefore, Cu can be uniformly diffused from the layer (B) into the layer (A), whereby the CIGS film 3′ is produced as containing crystal grains uniformly grown to greater sizes. Since the layer (B) containing Cu is once provided in the solid phase, Cu₍₂₋ₓ₎Se is substantially prevented from being excessively incorporated into the film. Further, the thermally sublimated Se vapor is supplied in the heating step, so that Se is substantially prevented from being released outside the system in the heating step. Thus, the Cu—In—Ga composition ratio of the CIGS film 3′ can be controlled as desired.

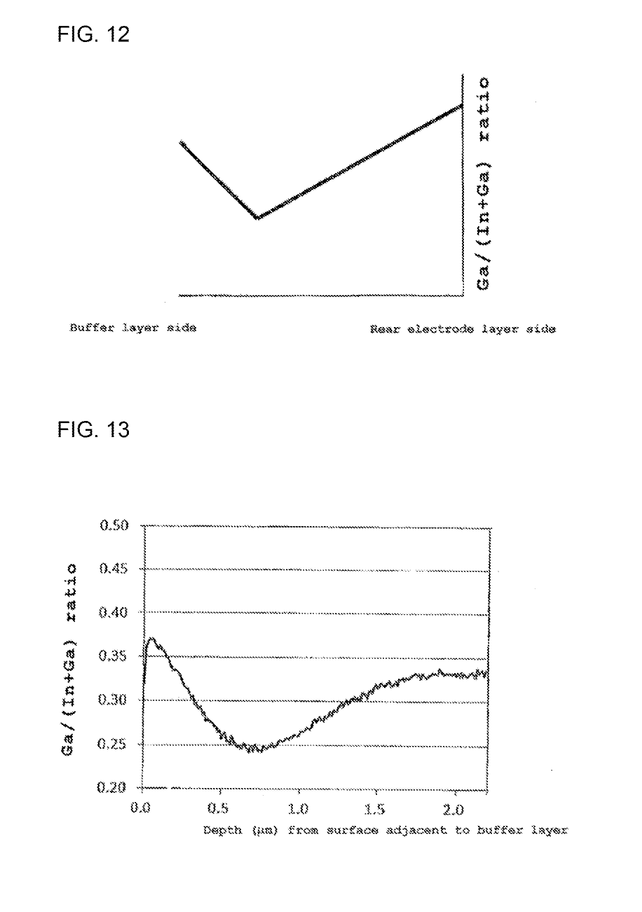

Further, the layer (C) containing In, Ga and Se is formed on the CIGS film 3′ at substantially the same temperature (550° C. or higher) as in the heating step, and the formation of the layer (C) is achieved by repeatedly stacking the gallium selenide film (Y) and the indium selenide film (X) in this order and increasing the thickness ratio (Y/X) between the gallium selenide film (Y) and the indium selenide film (X) as the stacking is repeated. Therefore, the Ga/(In+Ga) ratio of the layer (C) has a gradient opposite to that of the layer (A) along the thickness of the film. Thus, the CIGS film 3 can be produced as having a V-shaped Ga/(In+Ga) ratio profile (double-graded structure) as shown in FIG. 12.

In the embodiment described above, the formation of the layer (A) and the layer (B) is achieved with the substrate 1 maintained at a retention temperature of 200° C., but the retention temperature is preferably a temperature of 100° C. to 250° C., particularly preferably a temperature of 150° C. to 200° C. If the temperature is excessively high, it will be impossible to stack the layer (B) in the solid phase on the layer (A). If the temperature is excessively low, on the other hand, it will be difficult to form the layers by the vapor deposition.

In the embodiment described above, the stack 6 of the layer (A) and the layer (B) is heated for 15 minutes with the substrate 1 maintained at a retention temperature of 550° C. The temperature for the heating is preferably not lower than 520° C. The heating period is preferably 1 to 30 minutes, more preferably 2 to 15 minutes. This is because a certain period is required for sufficient crystal growth, although Cu is very rapidly diffused from the layer (B) into the layer (A).

In the embodiment described above, the CIGS film 3′ obtained after the heating step has an average Cu—In—Ga composition ratio of Cu/(In+Ga)≈1.00 (molar ratio) not by way of limitation, but may have a desired composition ratio. However, the Cu—In—Ga composition ratio of the CIGS film 3′ is preferably such as to satisfy an expression of 0.95<Cu/(In+Ga)<1.30 (molar ratio). If the Cu/(In+Ga) value is excessively small, sufficient crystal growth tends to be prevented due to Cu deficiency. If the Cu/(In+Ga) value is excessively great, on the other hand, Cu₍₂₋ₓ₎Se is excessively incorporated into the CIGS film 3′. Therefore, where the CIGS film 3′ is used for a device, the device is liable to have poorer device characteristics.

In the embodiment described above, the CIGS film 3 formed with the layer (C) in the post-stacking step has a Cu—In—Ga composition ratio of Cu/(In+Ga)≈0.77 (molar ratio) not by way of limitation, but may have a desired composition ratio. However, the molar ratio preferably satisfies an expression of 0.70<Cu/(In+Ga)<0.95. In this case, Cu₍₂₋ₓ₎Se can be prevented from being excessively incorporated into the CIGS film 3, and the CIGS film 3 is slightly Cu-deficient as a whole. Further, the ratio of Ga and In, which are the same group elements, is preferably 0.10<Ga/(In+Ga)<0.40.

In the embodiment described above, the CIGS film 3 has a thickness of 2.0 μm not by way of limitation, but may have a desired thickness. However, the thickness of the CIGS film 3 is preferably 1.0 to 3.0 μm, more preferably 1.5 to 2.5 μm. If the thickness is excessively small, the CIGS film serving as the light absorbing layer has a smaller light absorbing amount, thereby impairing the performance of the device. If the thickness is excessively great, on the other hand, a longer period is required for the formation of the film, thereby reducing the productivity.

In the embodiment described above, the Se vapor is supplied in the heating step and in the post-stacking step. Instead of the Se vapor, H₂Se may be supplied. In this case, the supply of H₂Se provides the same effect as the supply of the Se vapor. Where a minimum amount of Se is released outside the CIGS film 3′ and the CIGS film 3, there is no need to supply the Se vapor and H₂Se.

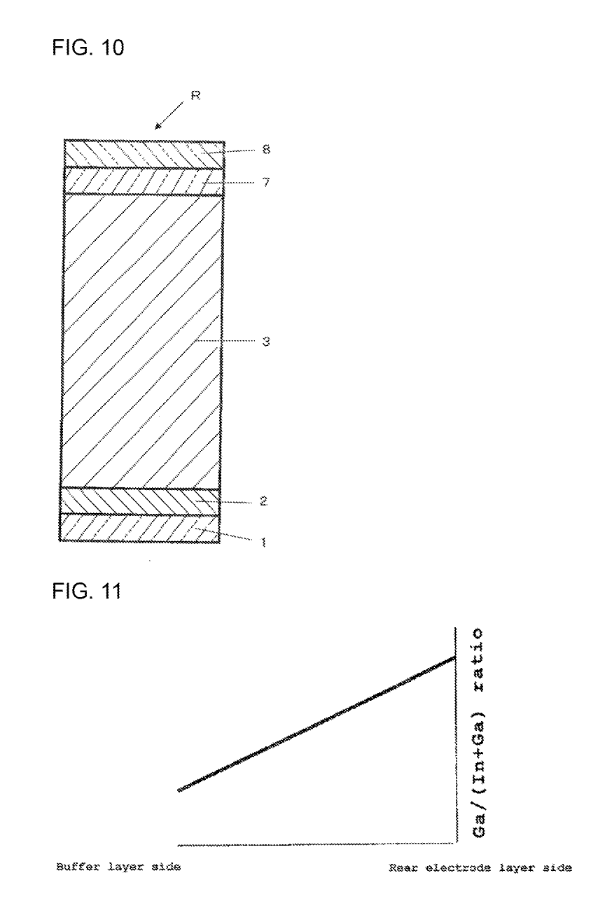

Next, the construction of a CIGS solar cell R employing the CIGS film 3 as a light absorbing layer and a production method for the CIGS solar cell R will be described below. As shown in FIG. 10, the CIGS solar cell R includes the CIGS film 3 produced in the aforementioned manner, and a buffer layer 7 and a transparent electrically-conductive layer 8 stacked in this order over the CIGS film 3.

More specifically, a buffer layer 7 including a cadmium sulfide layer (having a thickness of 50 nm) and a ZnO layer (having a thickness of 50 nm) is first formed over the CIGS film 3 formed in the aforementioned manner. The buffer layer 7 is preferably made of a higher-resistance n-type semiconductor so as to form a pn junction with the CIGS film 3. A single buffer layer such as of ZnMgO or Zn(O,S) may be used instead of the CdS buffer layer and the ZnO buffer layer. The buffer layer 7 preferably has a thickness of 30 to 200 nm. Where the buffer layer has a single layer structure, the single buffer layer preferably has a thickness of 30 to 200 nm. The plural types of layers thus stacked as the buffer layer advantageously form the pn junction with the CIGS film 3. If the pn junction can be properly formed, the plural types of layers are not necessarily required.

Then, a transparent electrically-conductive film 8 of indium tin oxide (ITO) (having a thickness of 200 nm) is formed on the buffer layer 7 by a sputtering method. The transparent electrically-conductive layer 8 is preferably made of a material having a higher transmittance. Examples of the material other than ITO include indium zinc oxide (IZO) and aluminum zinc oxide (Al:ZnO). The transparent electrically-conductive film 8 preferably has a thickness of 100 to 300 nm. In this manner, the CIGS solar cell R is produced, which includes the rear electrode layer 2, the CIGS film 3, the buffer layer 7 and the transparent electrically-conducive layer 8 stacked in this order over the substrate 1.

In the CIGS solar cell production method, as described above, the CIGS film 3 is used as the light absorbing layer. Therefore, the CIGS solar cell R can be produced as having a higher conversion efficiency substantially without device-to-device variations in conversion efficiency. In addition, Cu₍₂₋ₓ₎Se is not formed in excess in the CIGS film 3 serving as the light absorbing layer, so that the CIGS solar cell R is free from reduction in cell characteristics and has a higher efficiency. Further, the CIGS film 3 has a V-shaped Ga/(In+Ga) ratio profile (double-graded structure) along the thickness thereof as shown in FIG. 12, so that the CIGS solar cell R has a further higher conversion efficiency.

In the embodiment described above, the CIGS solar cell R includes the substrate 1, the rear electrode layer 2, the CIGS film 3, the buffer layer 7 and the transparent electrically-conductive layer 8. As required, a metal electrode may be provided on the transparent electrode layer 8.

Next, inventive examples will be described in conjunction with comparative examples. It should be understood that the present invention be not limited to these inventive examples.

### EXAMPLES

### Example 1

A CIGS solar cell was produced in the same manner as in the embodiment described above. More specifically, a SLG substrate (having a size of 30×30 mm and a thickness of 0.55 mm) was prepared, and Mo was deposited (to a thickness of 500 nm) over the substrate to form a rear electrode layer. While the substrate was maintained at a retention temperature of 200° C., a layer (A) was formed over the rear electrode layer under the following conditions.

### <Formation of Layer (A)>

With the use of substantially the same apparatus as the evaporation apparatus 9 shown in FIG. 2, a gallium selenide film (Y) was first formed while the temperature of a Ga evaporation source was controlled at 1000° C. and the temperature of a Se evaporation source was controlled at 180° C. Then, an indium selenide film (X) was formed while the temperature of an In evaporation source was controlled at 850° C. and the temperature of the Se evaporation source was controlled at 180° C. Thus, the gallium selenide film (Y) and the indium selenide film (x) were stacked. The stacking was repeated five times, and the temperature of the Ga evaporation source was controlled to be reduced as the stacking was repeated. Thus, a layer (A) was formed. The thickness ratios (Y/x) between the gallium selenide film and the indium selenide film are shown below in Table 1, and the temperatures of the Ga evaporation sources for the respective stacking operations are shown below in Table 2. It was preliminarily confirmed that the total thickness of the indium selenide films (formed by the five stacking operations) was 1.2 μm, and the total thickness of the gallium selenide films (formed by the five stacking operations) was 0.7 μm.

In turn, Cu and Se were vapor-deposited on the layer (A) to forma layer (B). Thus, a stack was formed. While a very small amount of Se vapor was supplied to the stack, the stack was heated for 15 minutes with the substrate maintained at a retention temperature of 550° C. to cause crystal growth. Thus, a CIGS film intermediate product was produced. While a very small amount of Se gas was supplied to the CIGS film intermediate product with the substrate maintained at a retention temperature of 550° C., a layer (C) was formed on the CIGS film intermediate product under the following conditions. Thus, a CIGS film (having a thickness of 2.0 μm) formed with the layer (C) by post-stacking was produced. A graph showing a variation in Ga/(In+Ga) ratio along the thickness of the CIGS film is shown in FIG. 13. A first buffer layer of CdS (having a thickness of 50 nm), a second buffer layer of ZnO (having a thickness of 70 nm) and a 200-nm thick transparent electrode layer of ITO were formed on the CIGS film. Thus, a CIGS solar cell of Example 1 was produced.

### <Formation of Layer (C)>

With the use of substantially the same apparatus as for the formation of the layer (A), the formation of the layer (C) was achieved in substantially the same manner as the formation of the layer (A) by repeating the stacking of the gallium selenide film (Y) and the indium selenide film (X) three times, except that the temperatures of the Ga evaporation sources were changed as shown below in Table 2. The temperatures of the Ga evaporation sources for the respective stacking operations are shown below in Table 2, and the thickness ratios (Y/x) between the gallium selenide film and the indium selenide film are shown below in Table 1.

### Example 2

A CIGS solar cell of Example 2 was produced in substantially the same manner as in Example 1, except that the number of times of the stacking of the gallium selenide film (Y) and the indium selenide film (x) and the temperatures of the Ga evaporation sources for the respective stacking operations were changed as shown below in Table 2 for the formation of the layer (A) and the layer (C). The times required for the formation of the respective films were reduced so that the CIGS film had the same thickness as in Example 1.

### Comparative Example 1

### Conventional Three-Step Method

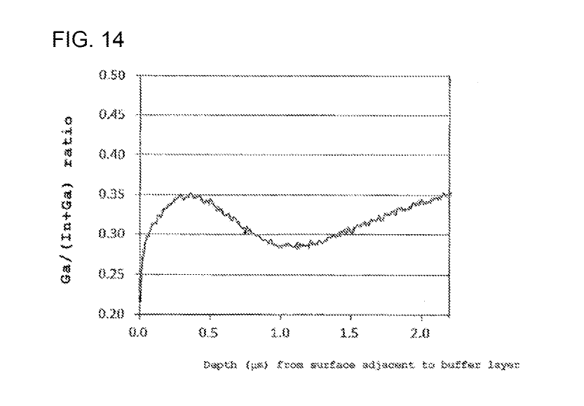

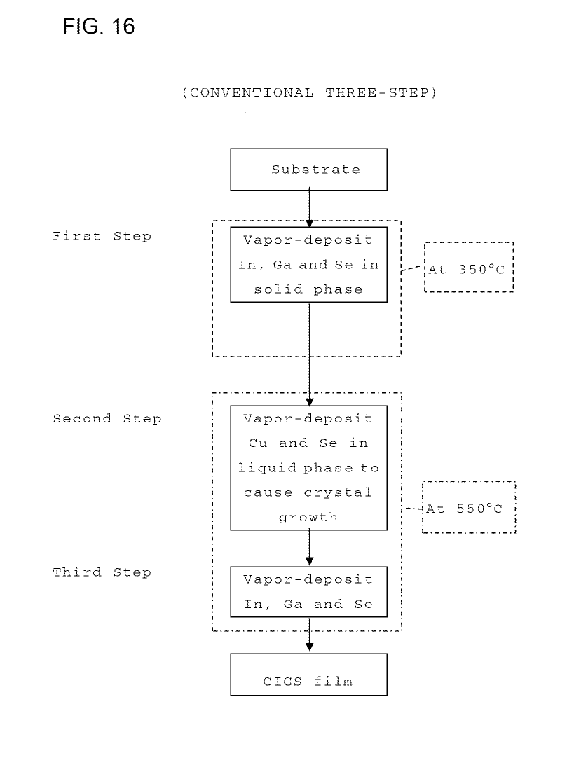

A substrate formed with a rear electrode layer was prepared as in Example 1. With the substrate maintained at a retention temperature of 350° C., In, Ga and Se were simultaneously vapor-deposited on the substrate to form a layer of In, Ga and Se. With the substrate heated to be maintained at a retention temperature of 550° C., Cu and Se were vapor-deposited on the layer of In, Ga and Se, followed by crystal growth. Thus, a CIGS film intermediate product (not shown) was produced. While a very small amount of Se vapor was supplied to the CIGS film intermediate product, In, Ga and Se were simultaneously vapor-deposited with the substrate maintained at a retention temperature of 550° C. Thus, a CIGS film (having a thickness of 2.0 μm) was produced. A production method for the CIGS film is schematically shown in FIG. 16, and a graph showing a variation in Ga/(In+Ga) ratio along the thickness of the film is shown in FIG. 14. Then, a buffer layer and a transparent electrode layer were formed over the CIGS film as in Example 1. Thus, a CIGS solar cell of Comparative Example 1 was produced.

### Comparative Example 2

A CIGS solar cell of Comparative Example 2 was produced in substantially the same manner as in Example 1, except that the temperature of the Ga evaporation source was kept unchanged at 960° C. in the repeated stacking operations for the formation of the layer (A) and the layer (C). In Comparative Example 2, the thickness ratios (Y/X) between the gallium selenide film (Y) and the indium selenide film (X) were kept constant in the repeated stacking operations for the formation of the layer (A) and the layer (C).

TABLE 1

| | | | |
|---|---|---|---|
| | | Comparative | Comparative |
| Example 1 | Example 2 | Example 1 | Example 2 |

Thickness ratio (Y/X)

| | | | | | |
|---|---|---|---|---|---|
| Layer A | First stacking | 1.0 | 1.0 | Produced by | 0.6 |
| | Second stacking | 0.8 | 0.9 | Conventional | 0.6 |
| | Third stacking | 0.6 | 0.7 | three-step | 0.6 |
| | Fourth stacking | 0.4 | 0.6 | method | 0.6 |
| | Fifth stacking | 0.3 | 0.5 | | 0.6 |
| | Sixth stacking | — | 0.3 | | — |
| Layer C | First stacking | 0.3 | 0.3 | | 0.6 |
| | Second stacking | 0.6 | 0.6 | | 0.6 |
| | Third stacking | 1.0 | 0.8 | | 0.6 |
| | Fourth stacking | — | 1.0 | | — |

| | | | | |
|---|---|---|---|---|
| Average conversion efficiency (%) | 15.6 | 15.5 | 13.6 | 14.4 |
| Maximum conversion efficiency (%) | 16.4 | 16.2 | 14.8 | 15.5 |
| Ga inflection point (μm) | 0.6 | 0.7 | 0.6 | 0.6 |
| Ga inflection point ratio | 0.64 | 0.61 | 0.86 | 0.83 |

Ten such CIGS solar cells were produced for each of Examples and Comparative Examples. Then, the conversion efficiencies of the CIGS solar cells were each measured in the following manner. For each of Examples and Comparative Examples, the Ga inflection point ratio of the CIGS film and the depth of the inflection point from the front surface of the CIGS film were measured and calculated in the following manner. Together with the thickness ratios (Y/X) between the gallium selenide film (Y) and the indium selenide film (X), the results of the measurement and the calculation are shown above in Table 1.

[Conversion Efficiency]

For each of Examples and Comparative Examples, the conversion efficiency of the CIGS solar cell was measured by applying artificial sunlight (AM1.5) to an area over the front surface of the CIGS solar cell by means of a solar simulator (CELL TESTER YSS150 available from Yamashita Denso Corporation).

[Ga Inflection Point and Calculation of Ga Inflection Point Ratio]

For each of Examples and Comparative Examples, the In—Ga ratio of the CIGS film was determined by a D-SIM evaluation (DYNAMIC SIMS evaluation). A Ga ratio maximum point and a Ga ratio minimum point were detected in the film, and an inflection point was calculated based on these values. At this time, a distance between the front surface of the CIGS film and the Ga ratio minimum point was measured to define a Ga inflection point (μm).

TABLE 2

| | | | | Compar- | Compar- |
|---|---|---|---|---|---|
| | | | | ative | ative |
| | | Example 1 | Example 2 | Example 1 | Example 2 |
| Temperatures (° C.) of | | | | | |
| Ga evaporation sources | | | | | |
| Layer | First stacking | 1000 | 1000 | Produced | 960 |
| A | Second stacking | 975 | 990 | by | 960 |
| | Third stacking | 960 | 970 | conven- | 960 |
| | Fourth stacking | 945 | 960 | tional | 960 |
| | Fifth stacking | 930 | 940 | three-step | 960 |
| | Sixth stacking | — | 930 | method | — |
| Temperatures (° C.) of | | | | | |
| Ga evaporation sources | | | | | |
| Layer | First stacking | 930 | 930 | | 960 |
| C | Second stacking | 960 | 960 | | 960 |
| | Third stacking | 1000 | 980 | | 960 |
| | Fourth stacking | — | 1000 | | — |

The temperatures of the In evaporation sources for the layer A and the layer C were 850° C.
The temperatures of the Se evaporation sources for the layer A and the layer C were 180° C.

The above results indicate that the CIGS solar cells of Examples each had a higher average conversion efficiency. By the inventive production method, the solar cells were each produced as having a higher efficiency with proper reproducibility. On the other hand, the CIGS solar cells of Comparative Examples each had a lower conversion efficiency than the CIGS solar cells of Examples with a greater Ga inflection point ratio and with a smaller difference between the Ga ratio maximum point and the Ga ratio minimum point.

While specific forms of the embodiment of the present invention have been shown in the aforementioned inventive examples, the inventive examples are merely illustrative of the invention but not limitative of the invention. It is contemplated that various modifications apparent to those skilled in the art could be made within the scope of the invention.

The inventive CIGS film production method is suitable for producing a CIGS film having excellent characteristic properties for use as a light absorbing layer for a CIGS solar cell with proper reproducibility. The inventive CIGS solar cell production method is suitable for producing a solar cell having a higher conversion efficiency with proper reproducibility.

1. A CIGS film production method comprising the steps of:
stacking a layer (A) containing indium, gallium and selenium and a layer (B) containing copper and selenium, in this order in a solid phase over a substrate; and
heating a resulting stack of the layer (A) and the layer (B) to melt the layer (B) into a liquid phase, whereby copper is diffused from the layer (B) into the layer (A) to cause crystal growth;
wherein the layer (A) is formed by repeatedly stacking a gallium selenide film (Y) and an indium selenide film (X) in this order and reducing a thickness ratio (Y/X) between the gallium selenide film (Y) and the indium selenide film (X) as the stacking is repeated.

2. The CIGS film production method according to claim 1, further comprising, after the heating step, a post-stacking step of stacking a layer (C) containing indium, gallium and selenium while maintaining the substrate at the same temperature as in the heating step,
wherein the layer (C) is formed by repeatedly stacking a gallium selenide film (Y) and an indium selenide film (X) in this order and increasing a thickness ratio (Y/X) between the gallium selenide film (Y) and the indium selenide film (X) as the stacking is repeated.

3. The CIGS film production method according to claim 1,
wherein a thickness ratio (Y/X)(i) between a gallium selenide film (Y) and an indium selenide film (X) stacked in the first stacking operation out of repeated stacking operations for the formation of the layer (A) is 0.5 to 1.3,
wherein a thickness ratio (Y/X)(ii) between a gallium selenide film (Y) and an indium selenide film (X) stacked in the last stacking operation for the formation of the layer (A) is 0.2 to 0.5, and
wherein the thickness ratios (i) and (ii) satisfy a relationship of (i)>(ii).

4. The CIGS film production method according to claim 2,
wherein a thickness ratio (Y/X)(iii) between a gallium selenide film (Y) and an indium selenide film (X) stacked in the first stacking operation out of repeated stacking operations for the formation of the layer (C) is 0.2 to 0.5,
wherein a thickness ratio (Y/X)(iv) between a gallium selenide film (Y) and an indium selenide film (X) stacked in the last stacking operation for the formation of the layer (C) is 0.5 to 1.3, and
wherein the thickness ratios (iii) and (iv) satisfy a relationship of (iv)>(iii).

5. The CIGS film production method according to claim 1, wherein the thickness ratios (Y/X) between the gallium selenide film (Y) and the indium selenide film (X) are each controlled by controlling an evaporation amount of gallium through variable temperature control of a gallium evaporation source.

6. The CIGS film production method according to claim 2, wherein the CIGS film satisfies a molar ratio of 0.95<copper/(indium+gallium)<1.30 at the end of the heating step, and satisfies a molar ratio of 0.70<copper/(indium+gallium)<0.95 at the end of the post-stacking step.

7. The CIGS film production method according to claim 1,
wherein the stacking step is performed at a temperature of 100° C. to 250° C.,
wherein the heating step is performed at a temperature of not lower than 520° C.

8. The CIGS film production method according to claim 1, wherein a temperature increasing rate of not less than 10° C./second is employed for temperature increase from the temperature of the stacking step to the temperature of the heating step.

9. The CIGS film production method according to claim 1, wherein selenium vapor or hydrogen selenide is supplied in the heating step, and a selenium partial pressure is maintained at a higher level in a front surface of the stack than in an inner portion of the stack.

10. A CIGS solar cell production method comprising the steps of:
providing a rear electrode layer over a substrate;
providing a light absorbing layer of a CIGS film;
providing a buffer layer; and
providing a transparent electrically-conductive layer;
wherein the light absorbing layer of the CIGS film is formed by the CIGS film production method according to claim 1 in the light absorbing layer providing step.
